(19) United States
(12) Patent Application Publication
(10) Pub. No.: US 2021/0082732 A1
(43) Pub. Date: Mar. 18, 2021

(54) REPULSION MESH AND DEPOSITION METHODS

(71) Applicant: Applied Materials, Inc., Santa Clara, CA (US)

(72) Inventors: Madhu Santosh Kumar Mutyala, Santa Clara, CA (US); Sanjay Kamath, Fremont, CA (US); Deenesh Padhi, Sunnyvale, CA (US)

(73) Assignee: Applied Materials, Inc., Santa Clara, CA (US)

(21) Appl. No.: 17/014,671

(22) Filed: Sep. 8, 2020

Related U.S. Application Data
(60) Provisional application No. 62/899,351, filed on Sep. 12, 2019.

(51) Int. Cl. H01L 21/683; H01L 21/311; H01J 37/32

(52) U.S. Cl. CPC H01L 21/6833; H01L 21/31116; H01J 2237/3321; H01J 2237/334; H01J 37/32715

(57) ABSTRACT

Exemplary deposition methods may include electrostatically chucking a semiconductor substrate at a first voltage within a processing region of a semiconductor processing chamber. The methods may include performing a deposition process. The deposition process may include forming a plasma within the processing region of the semiconductor processing chamber. The methods may include halting formation of the plasma within the semiconductor processing chamber. The methods may include, simultaneously with the halting, increasing the first voltage of electrostatic chucking to a second voltage. The methods may include purging the processing region of the semiconductor processing chamber.

### CROSS-REFERENCE TO RELATED APPLICATIONS

This application claims the benefit of, and priority to U.S. Provisional Patent Application No. 62/899,351, filed 12 Sep. 2019, the contents of which are hereby incorporated by reference in their entirety for all purposes.

### TECHNICAL FIELD

The present technology relates to semiconductor processes and chamber components. More specifically, the present technology relates to modified components and deposition methods.

### BACKGROUND

Integrated circuits are made possible by processes which produce intricately patterned material layers on substrate surfaces. Producing patterned material on a substrate requires controlled methods of formation and removal of exposed material. As device sizes continue to shrink, particle contamination may be an increasing challenge. During deposition methods, material may deposit on chamber components, and this material may fall to the substrate subsequent deposition, which may affect device quality.

Thus, there is a need for improved systems and methods that can be used to produce high quality devices and structures. These and other needs are addressed by the present technology.

### SUMMARY

Exemplary deposition methods may include electrostatically chucking a semiconductor substrate at a first voltage within a processing region of a semiconductor processing chamber. The methods may include performing a deposition process. The deposition process may include forming a plasma within the processing region of the semiconductor processing chamber. The methods may include halting formation of the plasma within the semiconductor processing chamber. The methods may include, simultaneously with the halting, increasing the first voltage of electrostatic chucking to a second voltage. The methods may include purging the processing region of the semiconductor processing chamber.

In some embodiments, the first voltage may be 200 V or less. The second voltage may be 500 V or more. The semiconductor substrate may be electrostatically chucked to a substrate support. The semiconductor processing chamber may include a showerhead, and the deposition process may occur with the semiconductor substrate positioned at a first distance from the showerhead. The substrate support may include a mesh disposed within the substrate support. The mesh may be characterized by a first mesh density at an interior location of the mesh, and the mesh may be characterized by a second mesh density at an exterior location of the mesh surrounding the interior location of the mesh. The method may further include repositioning the semiconductor substrate to a second distance from the showerhead when the first voltage is increased to the second voltage. The second distance may be greater than the first distance. The second distance may be more than 25% greater than the first distance. The deposition process may include depositing silicon oxide using tetraethyl orthosilicate.

Some embodiments of the present technology may encompass semiconductor processing chambers. The chambers may include a pedestal configured to support a semiconductor substrate. The chambers may include a conductive mesh incorporated within the pedestal. The conductive mesh may be characterized by a first mesh density at a central region of the conductive mesh, and the conductive mesh may be characterized by a second mesh density greater than the first mesh density at an exterior region of the conductive mesh.

In some embodiments the exterior region of the conductive mesh may be characterized by an annular shape encompassing the central region of the conductive mesh. The conductive mesh may be characterized by a radius extending from a central axis through the conductive mesh. The exterior region may extend up to about 30% of the radius from an exterior edge of the conductive mesh towards the central axis. The pedestal may be configured to vertically translate the semiconductor substrate within the semiconductor processing chamber. The processing chamber may also include a showerhead configured to operate as a plasma-generating electrode within the semiconductor processing chamber.

Some embodiments of the present technology may encompass deposition methods. The methods may include forming a plasma of an oxygen-containing precursor within a processing region of a semiconductor processing chamber. The processing region may house a semiconductor substrate on a substrate support. The methods may include, while maintaining the plasma of the oxygen-containing precursor, flowing a silicon-containing precursor into the processing region of the semiconductor processing chamber at a first flow rate. The methods may include ramping the first flow rate of the silicon-containing precursor over a period of time to a second flow rate greater than the first flow rate. The methods may include performing a deposition at the second flow rate of the silicon-containing precursor.

In some embodiments, the silicon-containing precursor may include tetraethyl orthosilicate. The period of time may be less than or about 10 seconds. Ramping the first flow rate may occur at a constant increase of from about 2 grams per second of the silicon-containing precursor to about 5 grams per second of the silicon-containing precursor. The deposition may be performed at a temperature of less than or about 400° C. The processing region of the semiconductor processing chamber may be maintained free of the silicon-containing precursor while forming the plasma of the oxygen-containing precursor. The semiconductor substrate may include silicon, and forming the plasma of the oxygen-containing precursor may produce an oxygen-radicalized surface termination of the silicon of the semiconductor substrate.

Such technology may provide numerous benefits over conventional systems and techniques. For example, the systems may limit or minimize deposition of falling particles subsequent deposition processes by repelling the particles during purging. Additionally, the operations of embodiments of the present technology may produce improved interfacial density of materials on a substrate, which may reduce undercut during subsequent etching. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a deposition method according to some embodiments of the present technology.

FIGS. 3A-3C show schematic views of exemplary conductive meshes according to some embodiments of the present technology.

FIG. 4 shows exemplary operations in a deposition method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During material deposition, such as of silicon oxide or other silicon-containing materials, plasma enhanced deposition may produce a local plasma between a showerhead or gas distributor, and a substrate support. As precursors are activated in the plasma, the deposition materials may form and deposit on the substrate. While this deposition is occurring, additional deposition may also occur in the processing chamber, such as dead zones within the chamber, where fluid flow may not be ideal. Additionally, the process of plasma generation may produce a sheath layer above the substrate, which may circulate and trap certain particles. When the plasma is turned off, materials attached to chamber components may flake off and fall to the substrate, and particles previously trapped in the plasma may also fall to the substrate. These additional particulates may produce defects on the deposited film, which may degrade or otherwise affect device quality.

Conventional technology has often accepted a certain amount of these residual particle effects. The present technology, however, may adjust processing sequences and utilize modified chamber components to prevent an amount of these defects. For example, the present technology may energize an electrostatic field to repulse these defect particles from the substrate, allowing them to be pulled from the chamber. By increasing portions of an internal mesh of the substrate support, electric field strength may be increased to maintain these particles off the substrate subsequent processing.

Additionally, processing with certain silicon precursors, such as tetraethyl orthosilicate, may produce lower density films, such as silicon oxide films. While some processes, such as gap filling and low quality formation, may be improved, interfacial regions of the film and an underlying substrate may be characterized by porous and weaker film coverage. During subsequent etch processing, such as dry or wet etching, upon reaching the underlying substrate, the etchant may undercut the deposited film along the interfacial region between the deposited film and the substrate, which may lead to further peeling and film degradation during subsequent polishing or processing operations.

Conventional techniques have addressed this issue by often utilizing alternative precursors for deposition, or performing higher temperature depositions, which may increase film density. The present technology may overcome these limitations by priming a substrate surface and forming a higher quality interface. This may allow a low density film to be formed, which may be useful during intermediate process operations, while limiting or preventing undercut during subsequent etching. Additionally, by improving interfacial film quality, deposition may be performed at lower temperatures, which may increase deposition rate over conventional processes. After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

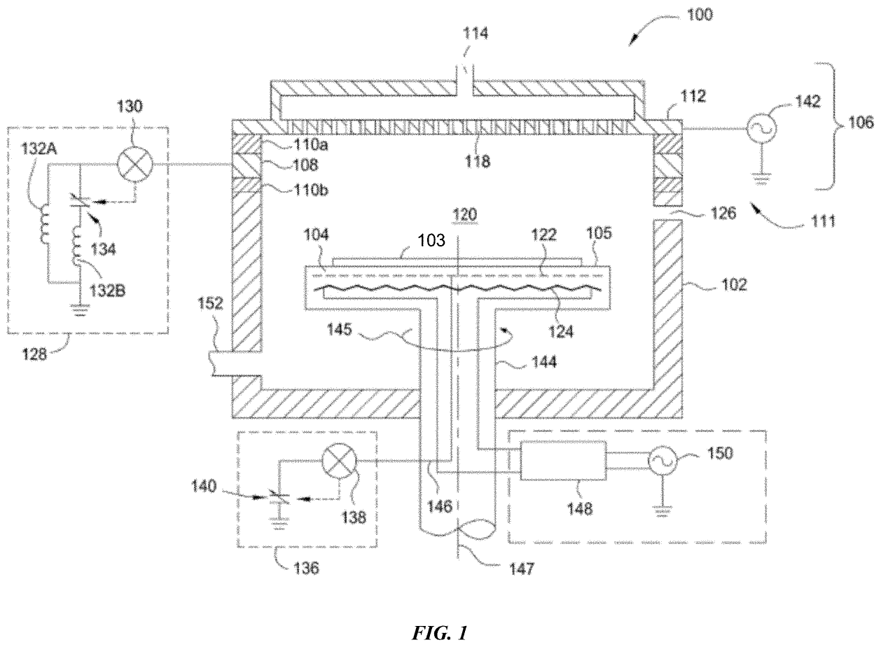

FIG. 1 shows a cross-sectional view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

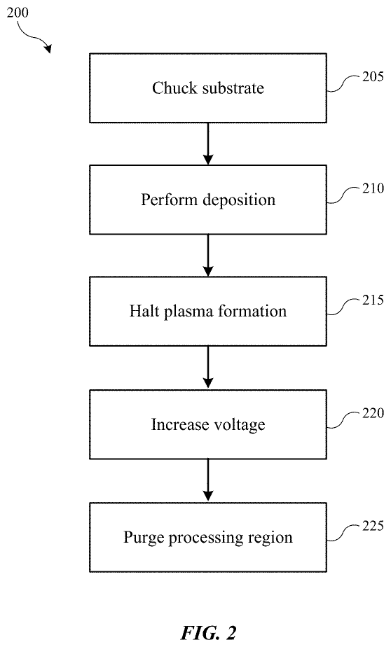

FIG. 2 shows exemplary operations in a deposition method 200 according to some embodiments of the present technology. The method may be performed in a variety of processing chambers, including processing chamber 100 described above. Additional aspects of processing chamber 100 will be described further below. The method may include utilizing a particular substrate support mesh in a process to limit or prevent particle contamination. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above. At operation 205, the substrate may be electrostatically chucked at a first voltage within the processing region of the semiconductor processing chamber. The pedestal may include a conductive mesh disposed within the substrate support, such as third electrode 124, for example. A voltage may be applied to the substrate to clamp the substrate to compensate for and limit tensile effects on the substrate.

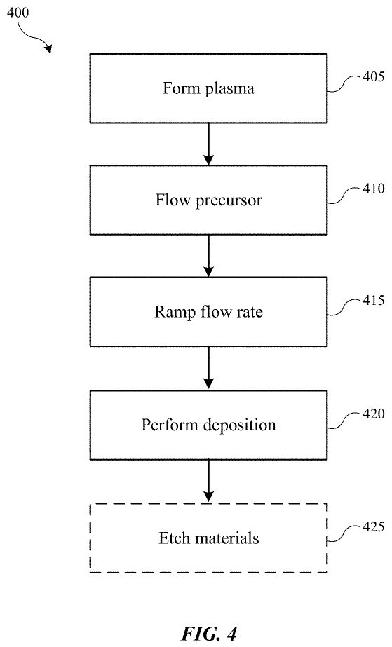

A deposition process may be performed at operation 210, in which a material is deposited on the substrate. In exemplary embodiments, the deposition process may involve forming a plasma within the processing region of the semiconductor processing chamber to perform a plasma-enhanced deposition process of any of a variety of materials, for example, although non-plasma deposition processes may also be performed. An exemplary process may involve depositing silicon oxide, and may include utilizing tetraethyl orthosilicate as a precursor. An exemplary deposition process that may be performed is discussed below with respect to FIG. 4, although this process is not intended to be limiting to the variety of deposition processes encompassed by the present technology, or the processes for which the present particle repulsion and purging operations may be performed. Subsequent the deposition, the process may be completed or stopped. This may include halting formation of the plasma within the semiconductor processing chamber at operation 215, and purging the chamber.

Conventional processing may de-chuck the substrate during plasma purging. For example, when the plasma is switched off, and a pumping or exhaust system is engaged to remove byproducts or residual precursor materials, many conventional systems may also switch off the voltage for electrostatic chucking. When the plasma is halted, particles that may have been suspended in the plasma sheath may then fall to the wafer and contaminate the surface. Additionally, when a purge operation is initiated, particles or deposition materials that have attached to a showerhead or chamber surfaces, may be detached. Although a portion of this material will be properly purged from the chamber, some of these particles may also be pulled from surfaces and fall to the substrate surface causing further contamination. As previously noted, many conventional technologies may simply accept this amount of contamination, and attempt to rectify the issue with additional polishing or post processing, for example.

The present technology may adjust the purging process, or the transition between processing and purging, relative to conventional technologies. For example, while many conventional operations switch off the electrostatic chucking, the present technology may maintain the voltage applied for chucking. As discussed above, embedded electrodes, such as third electrode 124 described previously, may create an electrostatic or clamping force that seats the wafer, and limits deflection. Put another way, the electrode creates an electrostatic field that radiates through the wafer, and in addition to the clamping force created, the field may provide an electrostatic repulsive force extending through the wafer. This force may be proportional to the magnitude of charge on the particle as well as on the substrate, due to the electrostatic chucking.

The voltage utilized for electrostatic chucking may be a first voltage that may be around 200 V or less. The force acting upon the wafer is in part related to the amount of conductive material in the mesh, which may be considered a mesh density, or amount of area of the mesh containing or being conductive material. A standard mesh used for electrostatic chucking may be a regular wire mesh with a consistent pattern and mesh density across the electrode. This mesh, in combination with the voltage applied, may provide adequate chucking. However, for producing a sufficient repulsive force to limit particle contamination as discussed above, the mesh and/or the voltage may be insufficient. For example, the density of the mesh and the first voltage applied to the mesh may not provide a sufficient magnitude of charge directed towards the particles, which may still overcome the force and fall to the substrate. The present technology may perform one or more modifications to the materials and methods performed, which may produce an adequate repulsive force to reduce or limit the contaminant particles reaching the substrate surface.

As will be explained further below, some embodiments of the present technology may incorporate a mesh having increased mesh density over a standard mesh, and a pedestal or substrate support utilized during method 200 may include a conductive mesh characterized by any of the density patterns described below. Additionally, or alternatively, the present technology may utilize an applied chucking voltage during plasma purge operations, which may produce an electrostatic repulsive force against particles within a processing environment. As noted above, method 200 may include halting the plasma formation and/or deposition at operation 215. Unlike conventional technologies that may similarly halt the electrostatic chucking, the present technology may maintain the electrostatic chucking, and may increase the voltage in some embodiments. For example, at operation 220, and simultaneously with halting the plasma, or switching off the plasma, the method may include increasing the first voltage of electrostatic chucking to a second voltage greater than the first. This may produce an electric field providing a repulsive force to particles that may otherwise fall to the substrate.

At operation 225, the processing region of the semiconductor processing chamber may be purged. This may involve maintaining or increasing operation of an exhaust or pumping system coupled with the processing chamber, as may occur typically in semiconductor processing. Because the electrostatic force repelling particles may be maintained during this purging operation, the contaminant particles may be removed prior to falling on the substrate.

As discussed above, electrostatic chucking may apply a voltage of about 200 V or less in some embodiments. When meshes with enhanced mesh density are incorporated with substrate supports, such as used for third electrode 124, according to embodiments of the present technology, less voltage may be utilized to maintain a similar clamping effect. Because the strength of the electric field may be increased with increased mesh density, the voltage may be reduced to provide similar chucking. Accordingly, in some embodiments, and depending on the configuration of the conductive mesh, the first voltage may be less than or about 200 V, and may be less than or about 180 V, less than or about 160 V, less than or about 150 V, less than or about 140 V, less than or about 130 V, less than or about 120 V, less than or about 110 V, less than or about 100 V, less than or about 90 V, or less.

When the voltage is transitioned from the first voltage to the second voltage, which may happen substantially instantaneously as an adjustment to the processing chamber, the voltage may be increased to greater than or about 300 V, and may be increased to greater than or about 400 V, greater than or about 500 V, greater than or about 600 V, greater than or about 700 V, greater than or about 800 V, greater than or about 900 V, or more. Although there may be correlation between increased voltage applied to the conductive mesh and the reduction in particle repulsion, increasing the voltage beyond a certain threshold, depending on substrate characteristics, may cause the substrate to bow, deform, or even break from the clamping force being applied. Accordingly, in some embodiments the second voltage may be maintained less than or about 1,100 V, and may be maintained less than or about 1,000 V, less than or about 900 V, less than or about 800 V, or less.

Processing operations may also be affected by the distance maintained between a substrate and a showerhead. As described with chamber 100, a pedestal or substrate support may be vertically translatable in some embodiments, and may position a substrate near the showerhead, such as gas distributor 112, during some deposition or other processing operations. The substrate may be maintained at this first distance from the showerhead throughout the deposition process. In some processing chambers encompassed by the present technology, exhaust flows may extend below the substrate support, such as with outlet 152 of FIG. 1. When the distance between the substrate and the showerhead is maintained sufficiently low, purge flow may not fully extend across the substrate. Accordingly, in some embodiments, method 200 may optionally include repositioning the substrate support during the purging operation.

For example, once plasma formation has been switched off or halted, and a purging operation may begin, the pedestal may reposition the substrate to a second distance from the showerhead, which may be a distance greater than the first distance. This may also occur when or while the first voltage is increased to the second voltage. By increasing the distance between the components, an exhaust flow may better draw across the showerhead, and may improve particle or contaminant removal. Accordingly, by increasing the distance, improved removal may be afforded. Hence, in some embodiments the second distance may be at least 25% greater than the first distance, and in some embodiments the second distance may be greater than or about 150% of the first distance, and may be greater than or about 200% of the first distance, greater than or about 250% of the first distance, greater than or about 300% of the first distance, greater than or about 350% of the first distance, greater than or about 400% of the first distance, greater than or about 450% of the first distance, greater than or about 500% of the first distance, greater than or about 550% of the first distance, or greater.

By performing an electrostatic repulsion according to embodiments of the present technology, particle contamination may be reduced relative to conventional technologies. For example, depending on the conductive mesh and voltage applied, experiments have illustrated that the particles of a threshold size were reduced from over one thousand particles to less than 300 particles. Increased mesh density may further reduce the particle contamination, at increased voltages as described, to less than or about 30% of a baseline amount of particles during conventional operations described previously, and may reduce particles to less than or about 25% of baseline particles, less than or about 20% of baseline particles, less than or about 15% of baseline particles, less than or about 14% of baseline particles, less than or about 13% of baseline particles, less than or about 12% of baseline particles, less than or about 11% of baseline particles, less than or about 10% of baseline particles, less than or about 9% of baseline particles, less than or about 8% of baseline particles, less than or about 7% of baseline particles, less than or about 6% of baseline particles, less than or about 5% of baseline particles, less than or about 4% of baseline particles, or less.

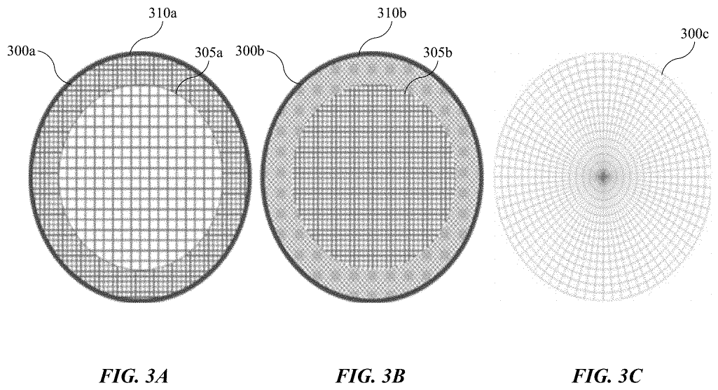

FIGS. 3A-3C show schematic views of exemplary conductive meshes 300 according to some embodiments of the present technology. As previously explained, some conductive mesh embodiments may be characterized by an area of increased mesh density relative to another area across the mesh. Conductive meshes 300 may be incorporated within pedestals or substrate supports as previously described for any number of exemplary processing chambers. For example, conductive meshes 300 may be third electrode 124 as discussed above, and may be incorporated into the pedestal within a semiconductor processing chamber. Exemplary pedestals may be vertically translatable to bring a substrate towards or away from a showerhead of exemplary chambers. The showerheads may be configured to operate as a plasma-generating electrode within the chambers in some embodiments.

As illustrated in FIG. 1, gas distributor 112 may have an area including apertures for delivering and distributing a precursor, although in edge regions there may not be any apertures, which may produce dead zones. These regions may be locations where deposition materials may collect and then flake off during purging. Consequently, particle density at an outer area of the substrate may be a greater issue than in a central region. In order to increase repulsion at edge regions of the substrate where particle accumulation may be increased, in some embodiments, an associated annular region of the conductive mesh may be characterized by a greater mesh density than another region. For example, FIG. 3A may illustrate an exemplary conductive mesh according to some embodiments of the present technology. Conductive mesh 300a may be characterized by a central region 305a, which may include a standard mesh pattern of conductive meshes, and which may be characterized by a first mesh density. Conductive mesh 300a may also be characterized by an exterior region 310a, which may include a second mesh density greater than the first.

As illustrated, exterior region 310a may be characterized by an annular shape extending about or encompassing the central region, although different geometries of conductive meshes are similarly encompassed by the present technology. For example, exterior region 310a may be similar to a frame about a central region, regardless of the geometry of the conductive mesh. The second mesh density may be greater than or about 1.5 times the first mesh density, and in some embodiments the second mesh density may be greater than or about 2.0 times the first mesh density, greater than or about 2.5 times the first mesh density, greater than or about 3.0 times the first mesh density, greater than or about 3.5 times the first mesh density, greater than or about 4.0 times the first mesh density, greater than or about 4.5 times the first mesh density, greater than or about 5.0 times the first mesh density, or greater. In some embodiments the second mesh density may be maintained below or about 5 times the first mesh density to maintain sufficient clamping across the wafer, as voltage may be adjusted with increased mesh density.

Conductive mesh 300a may be characterized by a radius extending from a central axis through the conductive mesh. The radius may be measured from any direction, and may accommodate any geometry as a measurement of length to an edge of the conductive mesh. In some embodiments, the exterior region 310a may encompass greater than or about 5% of the radius from an external edge of the conductive mesh towards the central axis, and in some embodiments may encompass greater than or about 10% of the radius, greater than or about 15% of the radius, greater than or about 20% of the radius, greater than or about 25% of the radius, greater than or about 30% of the radius, greater than or about 35% of the radius, greater than or about 40% of the radius, greater than or about 45% of the radius, greater than or about 50% of the radius, or more.

FIG. 3B illustrates a similar conductive mesh pattern as FIG. 3A, although both an interior or central region 305b first mesh density and the exterior region 310b second mesh density may be doubled relative to FIG. 3A. In operation, a reduced voltage may be applied with conductive mesh 300b as the increased conductive material may generate a greater magnitude of charge directed from the material. FIG. 3C illustrates an additional conductive mesh pattern 300c characterized by expanding rings and ribs extending from a center of the conductive mesh outward. Edge regions of a substrate may be more susceptible to particle effects as previously explained, and thus increased mesh density at external regions may improve these effects. Although a central region may also be characterized by increased mesh density, clamping effects may be generally greater in a central region of the substrate than at edge regions. Increasing an electrostatic force from increased mesh density in the central region may cause the substrate to bow in some situations depending on the applied voltage. Accordingly, in some embodiments the central or interior region of the conductive mesh may be characterized by reduced mesh density relative to an exterior region.

In addition to adjusting purging processes as described above, the present technology may additionally provide improved silicon oxide and other material deposition. The deposition techniques described below may be combined with any of the repulsive force processes or equipment described previously.

Tetraethyl orthosilicate (“TEOS”) may be characterized by a lower sticking coefficient than other silicon-containing precursors such as silane. While this effect may improve gap fill with reduced voids and overhang, this may similarly produce films with increased porosity and lower density. Although these characteristics may be sought in the bulk of the film being deposited, which may provide easier removal or etching, for example, increased porosity at an interface region may cause other challenges. For example, subsequent deposition, etching processes may be performed. When these etches reach the substrate, an undercut may occur to the film at the interfacial region. This may cause film peeling or chipping, which may be furthered with polishing operations.

Although densifying operations, such as anneals may improve this density, the anneal may densify the bulk of the film as well, which may remove the lower density sought, and may increase tensile stress through the film. This increased stress may also cause film peeling or other effects. Consequently, many conventional operations perform these depositions at relatively high temperatures, such as greater than or about 400° C., or greater than or about 500° C., which increases density throughout the film, but may be less than from an anneal. Because TEOS may deposit with more of a condensation-style effect, increased temperatures may also reduce the deposition rate.

The present technology may also improve low temperature deposition of oxide films deposited with TEOS by improving interfacial density of the film, while maintaining a porous, low density structure in the bulk, and increasing deposition rate over conventional techniques. The process may include ramping a rate of TEOS introduction into the processing chamber after radicalizing an interfacial surface of the substrate. This may improve bonding and lower porosity of the interfacial layer, prior to producing the lower density bulk region.

FIG. 4 shows exemplary operations in a method 400 of deposition according to some embodiments of the present technology. The method may be performed in one or more chambers, including any of the chambers previously described, and which may include any previously noted components, or utilize any methodology previously discussed subsequent processing. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. For example, and as described previously, operations may be performed prior to delivering a substrate into a processing chamber, such as processing chamber 100 described above, in which method 400 may be performed with or without some or all aspects of method 200 previously described.

Method 400 may include forming a plasma of an oxygen-containing precursor within a processing region of a semiconductor processing chamber at operation 405. The processing region may house a substrate, such as on a substrate support, and on which the deposition process may be performed. Any number of oxygen-containing precursors may be utilized including diatomic oxygen, ozone, nitrogen-containing precursors that incorporate oxygen, water, alcohol, or other materials. During the plasma formation initially, the processing region may be maintained substantially or completely free of a silicon-containing precursor, such as TEOS or any other silicon-containing precursor. Any number of inert or carrier gases may be delivered with the oxygen, including, for example, helium, argon, nitrogen, or other materials.

Subsequent a first period of time, and while the plasma of the oxygen-containing precursor is maintained, a silicon-containing precursor may be flowed into the processing region of the semiconductor processing chamber at operation 410. The silicon-containing precursor may be delivered at a first flow rate that may be below a target flow rate for depositing a lower density silicon-and-oxygen-containing material. The flow rate of the silicon-containing precursor may be ramped over a second period of time at operation 415. The flow rate may be ramped at a constant rate over the second period of time, or may be ramped at a scaling rate, either decreasing or increasing, during the second period of time until the silicon-containing precursor may reach the target flow rate. The deposition may then proceed at the target flow rate to produce a desired film thickness at operation 420. By performing processes according to method 400, during subsequent etching operations, such as during a wet or dry etch in optional operation 425, undercut etching at the film interface with an underlying structure may be minimized or prevented.

As noted above, the silicon-containing precursor may be TEOS in some embodiments, although other silicon-containing precursors are similarly encompassed by the present technology. The first period of time and the second period of time may be variable based on the substrate geometry and characteristics, as well as the target flow rate and initial flow rate of the precursor. In some embodiments either or both time periods may be less than or about 1 minute, and may be less than or about 30 seconds, less than or about 20 seconds, less than or about 15 seconds, less than or about 10 seconds, less than or about 9 seconds, less than or about 8 seconds, less than or about 7 seconds, less than or about 6 seconds, less than or about 5 seconds, less than or about 4 seconds, less than or about 3 seconds, less than or about 2 seconds, less than or about 1 second, or less.

In some embodiments the first flow rate may be less than or about 50% of the target flow rate of the silicon-containing precursor, and may be less than or about 40% of the target flow rate, less than or about 30% of the target flow rate, less than or about 20% of the target flow rate, less than or about 10% of the target flow rate, or less. By utilizing a lower flow rate, less silicon material may be formed at the initial deposition. This may afford adequate time for byproducts to escape the film, which may reduce porosity and increase the film density.

By utilizing the oxygen plasma initially, such as for example on a silicon or silicon-containing substrate, although the process may be similarly performed on any other material, the oxygen may radicalize the surface forming an oxygen-radicalized surface termination. Accordingly, this radicalized interface region may enhance reaction with the radical TEOS molecules when delivered, which may improve deposition at this surface. This may increase the density of the film prior to the increased deposition of a lower density film.

The ramping operation may be performed at a flow rate configured to slowly or quickly reach the target flow rate in some embodiments. For example, in some embodiments the flow rate may be increased at a rate of greater than or about 1 gram per second, and may be increased at a rate of greater than or about 2 grams per second, greater than or about 3 grams per second, greater than or about 4 grams per second, greater than or about 5 grams per second, greater than or about 6 grams per second, greater than or about 7 grams per second, greater than or about 8 grams per second, greater than or about 9 grams per second, greater than or about 10 grams per second, or more. Additionally, the flow rate may be increased within a range of from about 2 grams per second of the silicon-containing precursor to about 5 grams per second of the silicon-containing precursor. The flow rate ramping may also change over the ramping period to either go faster or slower over the ramping time. When the flow rate is ramped more slowly than this range, film deposition may not progress as uniformly, and extended exposure to plasma may impact the film. To improve uniformity of the delivery, a carrier gas as previously described may be provided at a flow rate of greater than or about 1 slm, and which may be greater than or about 2 slm, greater than or about 3 slm, greater than or about 4 slm, greater than or about 5 slm, greater than or about 6 slm, or greater.

When the flow rate is ramped more quickly than this range, deposition may occur more quickly, which may trap more byproducts, and may lead to increased porosity and lower density, as well as undercut of the film during etching. Accordingly, the flow rate may be increased at a measured rate to maintain a balance between film formation, and quality at the interface. The interfacial region may be characterized by a thickness of less than or about 10 nm prior to shifting to a lower density material, and in some embodiments the thickness of the higher density interfacial region may be less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less.

By providing an increased density film at the interface, lower temperature deposition may be performed, while maintaining a quality interface during subsequent operations, and which may limit or prevent undercut during etching. Consequently, the present technology may allow deposition to be performed at a temperature of less than or about 400° C., and which may be performed at a temperature of less than or about 390° C., less than or about 380° C., less than or about 370° C., less than or about 360° C., less than or about 350° C., less than or about 340° C., less than or about 330° C., less than or about 320° C., less than or about 310° C., less than or about 300° C., less than or about 290° C., or less.

By utilizing methods and components according to embodiments of the present technology, material deposition or formation may be improved. By providing densified material at an interface, film shrinkage may be reduced, and undercut may be limited of prevented. These improvements may reduce film peeling on a substrate, and may limit downstream damage to the film. Additionally, by performing particle repulsion operations as previously described, film contamination may be reduced over conventional techniques, which may increase device quality and yield.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A deposition method comprising:
electrostatically chucking a semiconductor substrate at a first voltage within a processing region of a semiconductor processing chamber performing a deposition process, wherein the deposition process comprises forming a plasma within the processing region of the semiconductor processing chamber;
halting formation of the plasma within the semiconductor processing chamber;
simultaneously with the halting, increasing the first voltage of electrostatic chucking to a second voltage; and
purging the processing region of the semiconductor processing chamber.

2. The deposition method of claim 1, wherein the first voltage is 200 V or less.

3. The deposition method of claim 1, wherein the second voltage is 500 V or more.

4. The deposition method of claim 1, wherein the semiconductor substrate is electrostatically chucked to a substrate support, wherein the semiconductor processing chamber comprises a showerhead, and wherein the deposition process occurs with the semiconductor substrate positioned at a first distance from the showerhead.

5. The deposition method of claim 4, wherein the substrate support comprises a mesh disposed within the substrate support, and wherein the mesh is characterized by a first mesh density at an interior location of the mesh, and wherein the mesh is characterized by a second mesh density at an exterior location of the mesh surrounding the interior location of the mesh.

6. The deposition method of claim 4, further comprising:
repositioning the semiconductor substrate to a second distance from the showerhead when the first voltage is increased to the second voltage, wherein the second distance is greater than the first distance.

7. The deposition method of claim 6, wherein the second distance is more than 25% greater than the first distance.

8. The deposition method of claim 1, wherein the deposition process comprises depositing silicon oxide using tetraethyl orthosilicate.

9. A semiconductor processing chamber comprising:
a pedestal configured to support a semiconductor substrate; and
a conductive mesh incorporated within the pedestal, wherein the conductive mesh is characterized by a first mesh density at a central region of the conductive mesh, and wherein the conductive mesh is characterized by a second mesh density greater than the first mesh density at an exterior region of the conductive mesh.

10. The semiconductor processing chamber of claim 9, wherein the exterior region of the conductive mesh is characterized by an annular shape encompassing the central region of the conductive mesh.

11. The semiconductor processing chamber of claim 10, wherein the conductive mesh is characterized by a radius extending from a central axis through the conductive mesh, and wherein the exterior region extends up to about 30% of the radius from an exterior edge of the conductive mesh towards the central axis.

12. The semiconductor processing chamber of claim 9, wherein the pedestal is configured to vertically translate the semiconductor substrate within the semiconductor processing chamber.

13. The semiconductor processing chamber of claim 9, further comprising a showerhead configured to operate as a plasma-generating electrode within the semiconductor processing chamber.

14. A deposition method comprising:
forming a plasma of an oxygen-containing precursor within a processing region of a semiconductor processing chamber, wherein the processing region houses a semiconductor substrate on a substrate support;
while maintaining the plasma of the oxygen-containing precursor, flowing a silicon-containing precursor into the processing region of the semiconductor processing chamber at a first flow rate;
ramping the first flow rate of the silicon-containing precursor over a period of time to a second flow rate greater than the first flow rate; and
performing a deposition at the second flow rate of the silicon-containing precursor.

15. The deposition method of claim 14, wherein the silicon-containing precursor comprises tetraethyl orthosilicate.

16. The deposition method of claim 14, wherein the period of time is less than or about 10 seconds.

17. The deposition method of claim 14, wherein ramping the first flow rate occurs at a constant increase of from about 2 grams per second of the silicon-containing precursor to about 5 grams per second of the silicon-containing precursor.

18. The deposition method of claim 14, wherein the deposition is performed at a temperature of less than or about 400° C.

19. The deposition method of claim 14, wherein the processing region of the semiconductor processing chamber is maintained free of the silicon-containing precursor while forming the plasma of the oxygen-containing precursor.

20. The deposition method of claim 14, wherein the semiconductor substrate comprises silicon, and wherein forming the plasma of the oxygen-containing precursor produces an oxygen-radicalized surface termination of the silicon of the semiconductor substrate.
